(19) United States
(12) Patent Application Publication
(10) Pub. No.: US 2016/0020371 A1
(43) Pub. Date: Jan. 21, 2016

(54) CHIP-ON-BOARD UV LED PACKAGE AND PRODUCTION METHOD THEREFOR

(71) Applicant: UVER CORPORATION LTD., Ansan-si, Gyeonggi-do (KR)

(72) Inventor: Young Hoon KANG, Suwon-si, Gyeonggi-do (KR)

(21) Appl. No.: 14/772,875

(22) PCT Filed: Mar. 4, 2014
(86) PCT No.: PCT/KR2014/001779

§ 371 Date: Sep. 4, 2015

(30) Foreign Application Priority Data
Mar. 4, 2013 (KR) 10-2013-0022909

(51) Int. Cl. H01L 33/60; H01L 33/54; H01L 25/00; H01L 33/00; H01L 25/075; H01L 33/62; H01L 33/48

(52) U.S. Cl. CPC H01L 33/60; H01L 33/62; H01L 33/54; H01L 33/486; H01L 33/005; H01L 25/0753; H01L 25/50; H01L 2933/0058; H01L 2933/0066; H01L 2933/005

(57) ABSTRACT

Disclosed is a chip-on-board UV LED package. The chip-on-board UV LED package comprises: a board in which electrode patterns are formed; a plurality of UV light sources which respectively comprise one or more UV LED chip and a correspondingly provided encapsulating material or lens, and are arrayed in a predetermined array on the board; and a reflecting means which is provided on the board so as to increase the focal length of the light emerging from the plurality of UV light sources. Here, the reflecting means comprises at least one reflector disposed so as to achieve separation between neighbouring UV light sources or between rows or columns of neighbouring UV light sources.

### TECHNICAL FIELD

The present invention relates to a chip-on-board ultraviolet (UV) light emitting diode (LED) package having a structure in which a plurality of UV LED chips are directly mounted on a board, and a method for manufacturing the same, and more particularly, to a chip-on-board UV LED package in which reflectors are provided between UV LED chips or between rows or columns of adjacent UV LED chips, and a method for manufacturing the same.

### BACKGROUND ART

A chip-on-board UV LED package has a structure in which a plurality of UV LED chips are mounted in an array on a board having a predetermined area.

In such a chip-on-board UV LED package, a large number of UV LED chips may be arranged within a predetermined area of a board to enhance an optical output and lower manufacturing costs.

In the chip-on-board UV LED package, the plurality of UV LED chips arranged on the board may be encapsulated by a single light-transmissive encapsulant.

The encapsulant may cover the entire area of one surface of the board with the plurality of UV LED chips arranged thereon.

In order to form such an encapsulant, a process of dispensing a light-transmissive resin may be performed.

However, the chip-on-board UV LED package has shortcomings in that it is difficult for the encapsulant covering the entirety of the plurality of UV LED chips to be formed as a lens having a parabolic shape, for example.

The method for manufacturing the chip-on-board UV LED package severely wastes a light-transmissive resin material for forming the encapsulant and increases an amount of light trapped within the encapsulant due to total internal reflection, degrading efficiency.

### DISCLOSURE

### Technical Problem

A technique for transmitting ultraviolet (UV) light more uniformly and for a greater distance is required in applying a chip-on-board UV LED for the purpose of UV curing.

In this connection, the application of reflectors covering the entirety of a plurality of UV LED chips mounted on a board may be considered.

However, this method may not be effective, in that a large number of UV LED chips may be present at a distance spaced apart from the reflectors and that light loss is made from an early stage.

An aspect of the present invention provides a chip-on-board UV LED package in which UV light is emitted more uniformly and for a greater distance through reflectors provided between UV light sources including UV LED chips or between rows or columns of the UV light sources.

### Technical Solution

According to an aspect of the present invention, there is provided a chip-on-board ultraviolet (UV) light emitting diode (LED) package including: a board on which electrode patterns are formed; UV light sources arranged in a predetermined array on the board and respectively including one or more UV LED chips and an encapsulant or a lens corresponding to the one or more UV LED chips; and a reflective unit provided on the board to increase an irradiation distance of light emitted from the plurality of UV light sources, wherein the reflective unit includes at least one reflector disposed to separate adjacent UV light sources or rows or columns of adjacent UV light sources.

According to an embodiment, the reflective unit may include a plurality of annular reflectors attached to the board such that the plurality of annular reflectors respectively surround the periphery of the UV light sources.

According to an embodiment, the reflective unit may include a plurality of linear reflectors attached to the board to separate rows or columns of adjacent UV light sources.

According to an embodiment, the reflective unit may include a plurality of reflectors, and the plurality of reflectors may include a mirror type reflector and a reflection prism reflector.

According to an embodiment, the reflective unit may form a reflective space by one or more reflectors, a plurality of UV light sources may be positioned in the reflective space, and the reflective space may be formed within the annular reflectors or between adjacent linear reflectors.

According to an embodiment, the board may include a plurality of chip mounting recesses formed to accommodate the one or more UV LED chips.

According to an embodiment, the reflective unit may include a grid-type reflector including a plurality of grid cells, and the plurality of grid cells may respectively form reflective spaces in which the UV light sources are accommodated.

According to another aspect of the present invention, there is provided a method for manufacturing a chip-on-board ultraviolet (UV) light emitting diode (LED) package including: a UV LED chip mounting operation of mounting a plurality of UV LED chips on a board; an encapsulant forming operation of forming a plurality of encapsulants encapsulating one or more of the plurality of UV LED chips on the board; and a reflector attaching operation of attaching one or more reflectors reflecting light from UV light sources including the plurality of UV LED chips or the plurality of UV LED chips and the plurality of encapsulants to the board before or after the plurality of UV LED chips are mounted.

According to an embodiment, the encapsulant forming operation may include: preparing a UV light-transmissive frame board having a plurality of molding recesses; filling the plurality of molding recesses with a UV-cured resin; mounting the board on the frame board such that the plurality of UV LED chips are inserted into the plurality of molding recesses filled with the UV-cured resin; and curing the UV-cured resin with UV light transmitted through the frame board to form the plurality of encapsulants.

### Advantageous Effects

The chip-on-board UV LED package according to the present disclosure has a structure in which a plurality of UV light sources each having a UV LED chip are arranged on a board and reflectors (or micro-reflectors) are provided between adjacent UV light sources or between rows or columns of the UV light sources, whereby UV light may be irradiated more uniformly and for a greater distance.

### DESCRIPTION OF DRAWINGS

FIG. 1 is a plan view illustrating a chip-on-board UV LED package according to an exemplary embodiment of the present disclosure;

FIG. 2 is a cross-sectional view illustrating the chip-on-board UV LED package, taken along line I-I of FIG. 1;

FIGS. 3A and 3B are cross-sectional views illustrating a method for manufacturing the chip-on-board UV LED package illustrated in FIGS. 1 and 2;

FIGS. 4A through 4E are plan views illustrating various embodiments of a chip-on-board UV LED package; and

FIGS. 5A through 5H are cross-sectional views illustrating various embodiments of a chip-on-board UV LED package.

### BEST MODE

Hereinafter, embodiments of the present disclosure will be described in detail with reference to the accompanying drawings.

These embodiments are provided so that this disclosure will fully convey the scope of the invention to those skilled in the art

The present disclosure may, however, be embodied in many different forms and should not be construed as being limited to the embodiments set forth herein.

In the drawings, widths, lengths, and thicknesses of elements may be exaggerated for the sake of convenience.

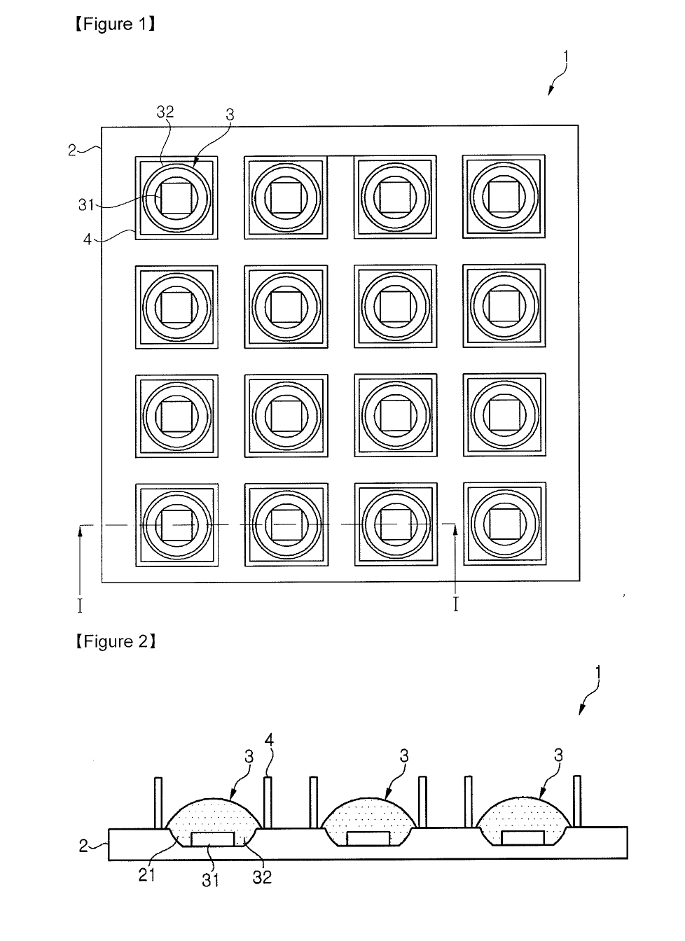

FIG. 1 is a plan view illustrating a chip-on-board UV LED package according to an exemplary embodiment of the present disclosure, and FIG. 2 is a cross-sectional view illustrating the chip-on-board UV LED package, taken along line I-I of FIG. 1.

As illustrated in FIGS. 1 and 2, a chip-on-board UV LED package 1 according to an exemplary embodiment of the present disclosure includes a board 2, a plurality of UV light sources arranged in a matrix form on the board 2, and a plurality of reflectors provided as reflective units to separate adjacent UV light sources 3.

Each of the UV light sources 3 includes a UV LED chip 31 and a light-transmissive encapsulant 32 formed to have a lens structure to cover the UV LED chip 31.

In the UV light sources 3, the encapsulant 32 may be omitted, or any other lens shape may be adopted, instead of the encapsulant 32.

The board 2 may be a printed circuit board (PCB) including a board main body formed of ceramics such as silicon, aluminum, copper, or an alloy material including these materials, and a plurality of electrode patterns formed on the board main body.

Each of the plurality of UV LED chips 31 is mounted on the board and connected to an electrode pattern on the board 2.

Each of the UV LED chips 31 is operated by power input through the electrode pattern to emit UV light having a wavelength ranging from about 200 nm to 420 nm.

Each of the encapsulants 32 is formed on the board to individually encapsulate the corresponding UV LED chip 31 to form a UV light source 3 together with the UV LED chip 31.

The encapsulant 32 may have various lens shapes, in addition to the substantially hemispherical lens shape as illustrated.

In the present exemplary embodiment, a plurality of chip mounting recesses 21 are formed on the board 2, and the UV LED chip 31 is mounted on each of the plurality of chip mounting recesses 21.

Electrode patterns for applying power to the corresponding UV LED chip 31 are at least partially formed within each of the chip mounting recesses 21.

At least a portion of the encapsulant 32 encapsulates the UV LED chip 31 positioned within each the chip mounting recesses 21.

The chip mounting recesses 21 may be formed through etching, laser beam machining, or any other processing scheme.

Each of the plurality of reflectors are attached to the board 2 to surround the periphery of the UV light source 3 to separate adjacent UV light sources 3.

All the UV light sources 3 on the board 2 may be isolated by the plurality of reflectors with respect to other UV light sources.

In the present exemplary embodiment, each of the reflectors has a quadrangular, annular cross-section to surround the circumference of the corresponding UV light source 3.

In the case of the reflector having an annular cross-section surrounding the periphery of the UV light source 3, a substantially quadrangular annular cross-section may help to minimize spaces between adjacent reflectors, where light does not reach.

Also, the reflector may be a mirror-type reflector formed of a highly reflective metal such as aluminum (Al) and gold (Au), a mirror or quartz.

A reflection prism reflector may also be used instead of the mirror-type reflector, or a mirror-type reflector and a reflection prism reflector may be combined to use reflection characteristics of both the mirror type reflector and the reflection prism type reflector.

The reflector may be attached to the board 2 before the UV LED chip 31 is mounted thereon, and alternatively, the reflector may be attached to the board 2 after the UV LED chip 31 is mounted thereon.

The chip-on-board UV LED package 1 configured as described above has an advantageously high output of UV light, enhanced uniformity of UV light, and irradiation of UV light for a greater distance.

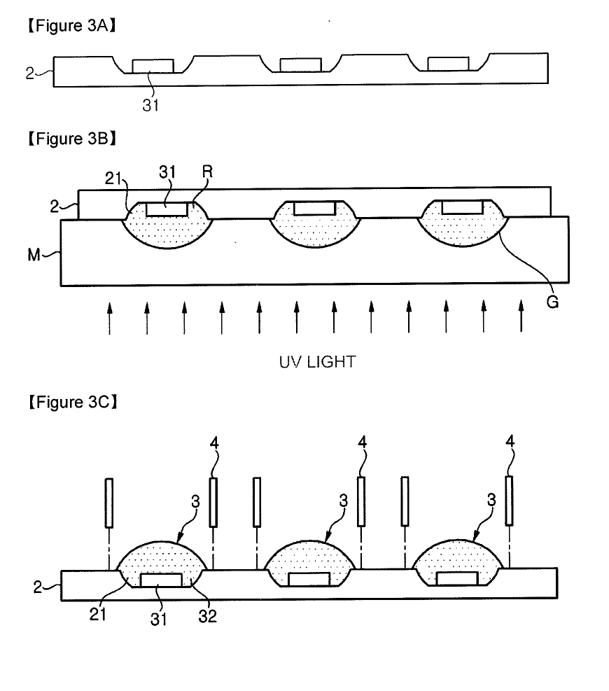

FIGS. 3A and 3B are cross-sectional views illustrating a method for manufacturing the chip-on-board UV LED package illustrated in FIGS. 1 and 2. Here, each of the UV LED chips 31 mounted on the board 2 is accommodated in the chip mounting recess 2.

Thereafter, as illustrated in FIG. 3B, a light-transmissive encapsulant 32 encapsulating the UV LED chip 31 is formed on the board 2.

In order to form the encapsulant 32, a frame board M including a plurality of molding recesses G is provided, and the board 2 on which the UV LED chips 31 are arranged is mounted on the frame board M such that the UV LED chips 31 are inserted into the molding recesses G filled with a UV curing resin R, respectively.

The frame board M has UV light transmittance, and the UV curing resin R is cured by a UV light source irradiated onto a lower portion of the frame board M to form an encapsulant individually covering the UV LED chips 31.

Thereafter, as illustrated in FIG. 3C, a plurality of reflectors 4 are attached to the board 2.

The reflectors 4 may be manufactured in advance and subsequently attached to the board 2.

According to the example illustrated in FIGS. 3A through 3C, a plurality of UV LED chips 31 are mounted on the board 2, and a plurality of encapsulants 32 are formed to cover the plurality of UV LED chips 31. After the plurality of UV light sources 3 are arranged on the board 3, the reflectors 4 are attached to the board 2. However, before the UV LED chips 31 are mounted, the reflectors 4 may be attached or formed on the board 2 in advance.

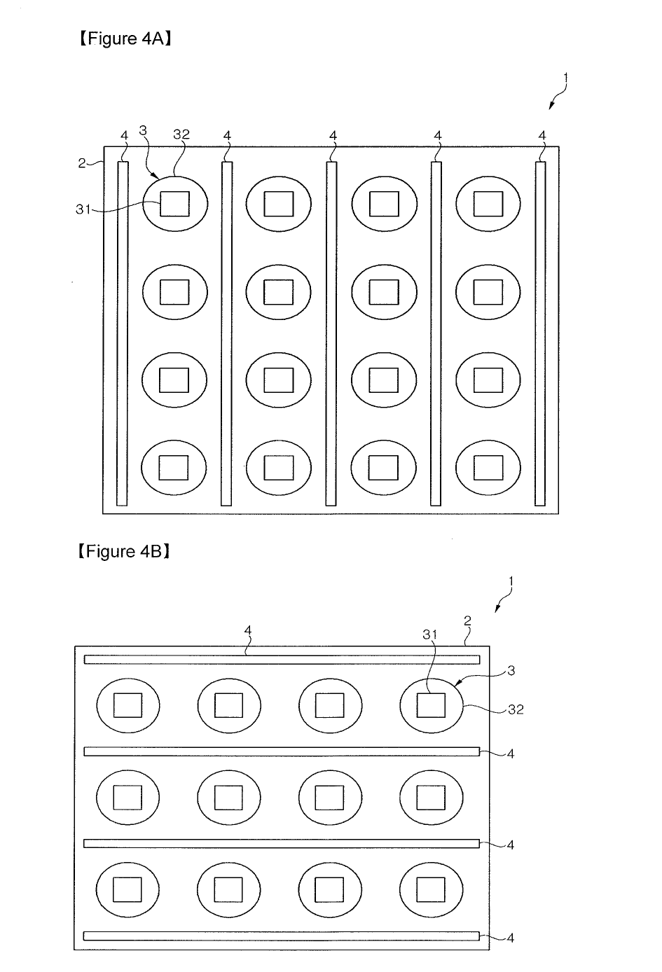

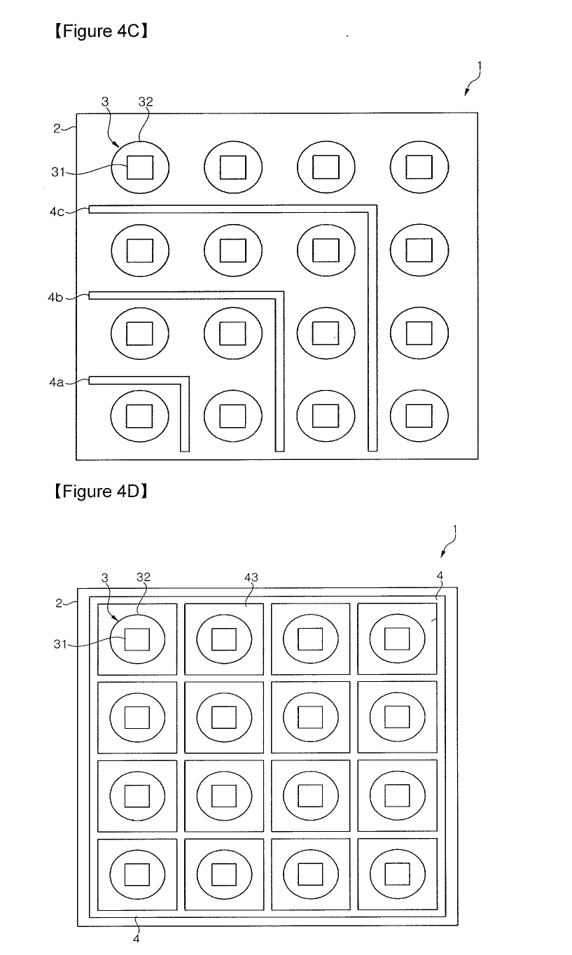

FIGS. 4A through 4E are plan views illustrating various embodiments of a chip-on-board UV LED package.

A chip-on-board UV LED package 1 of the exemplary embodiment illustrated in FIG. 4A includes a plurality of linear reflectors 4 having a length in a transverse direction and arranged to be parallel in a longitudinal direction on the board 2.

Each of the plurality of linear reflectors 4 is provided between rows of the UV LED chips 31 arranged in a matrix form or the UV light sources 3 including the same to separate the rows of the adjacent UV light sources 3.

Two adjacent linear reflectors 4 reflect light of UV light sources 3 of one row present therebetween.

The linear reflectors 4 may be a mirror type reflectors including a metal or a mirror or a reflective prism reflectors.

By combining the mirror type reflectors and the reflective prism reflectors on the single board 2, unique reflection characteristics of the mirror type reflectors and the reflective prism reflectors may be appropriately utilized.

A chip-on-board UV LED package 1 of the exemplary embodiment illustrated in FIG. 4B includes a plurality of linear reflectors 4 having a length in a longitudinal direction and arranged to be parallel in a transverse direction on the board 2.

Each of the plurality of linear reflectors 4 is provided between columns of the UV LED chips 31 arranged in a matrix form or the UV light sources 3 including the same to separate the columns of the adjacent UV light sources 3.

Two adjacent linear reflectors 4 reflect light of UV light sources 3 of one column present therebetween.

A chip-on-board UV LED package 1 of the exemplary embodiment illustrated in FIG. 4C includes a plurality of “ [symbol] ”-shaped linear reflectors 4a, 4b, and 4c having different sizes and arranged on the board 2.

Each of the plurality of “ [symbol] ”-shaped linear reflectors 4a, 4b, and 4c includes an in-between row reflective portion and an in-between column reflective portion perpendicularly connected to the in-between row reflective portion.

The first reflector 4a having the smallest size, among the plurality of “ [symbol] ”-shaped linear reflectors 4a, 4b, and 4c, separates one UV light source 3 in a first row and first column and three UV light sources 3 present in the first row and second column, in a second row and first column, and in the second row and second column. The second reflector 4b having a medium size separates the three UV light sources 3 present in the first row and second column, in a second row and first column, and in the second row and second column and five UV light sources 3 in the first row and third column, in the second row and third column, in a third row and third column, in a third row and first column, and in the third row and second column.

The largest third reflector 4c separates the five UV light sources 3 present in the first row and third column, in the second row and third column, in a third row and third column, in a third row and first column, and in the third row and second column and seven UV light sources 3 present in the first row and fourth column, in the second row and fourth column, in the third row and fourth column, in a fourth row and fourth column, in the fourth row and first column, in the fourth row and second column, and in the fourth row and third column.

A chip-on-board UV LED package 1 of the exemplary embodiment illustrated in FIG. 4D includes a grid-type reflector 4 attached to the board 2.

The grid-type reflector 4 includes a plurality of grid cells 43. Each of the plurality of UV light sources 3 is positioned in each of the plurality of grid cells 43.

Two adjacent UV light sources 3 are separated by four reflective walls provided in each of the grid cells 43.

In the chip-on-board UV LED packages 1 illustrated in FIGS. 4A through 4D, a single reflective wall provided in the reflector is positioned between two adjacent UV light sources 3. Compared with the exemplary embodiments illustrated in FIGS. 1 through 3, an area occupied by the reflectors on the board 2 is reduced and a ineffective space between reflectors due to absence of the UV light source is eliminated.

A chip-on-board UV LED package 1 of the exemplary embodiment illustrated in FIG. 4E includes a plurality of annular reflectors 4 surrounding the periphery of the UV light sources 3, like the chip-on-board UV LED package 1 of the exemplary embodiment illustrated in FIG. 1.

Unlike the reflectors 4 of the exemplary embodiment illustrated in FIG. 1 having a square or rectangular annular cross-section, the chip-on-board UV LED package 1 illustrated in FIG. 4E has a diamond-shaped annular cross-section.

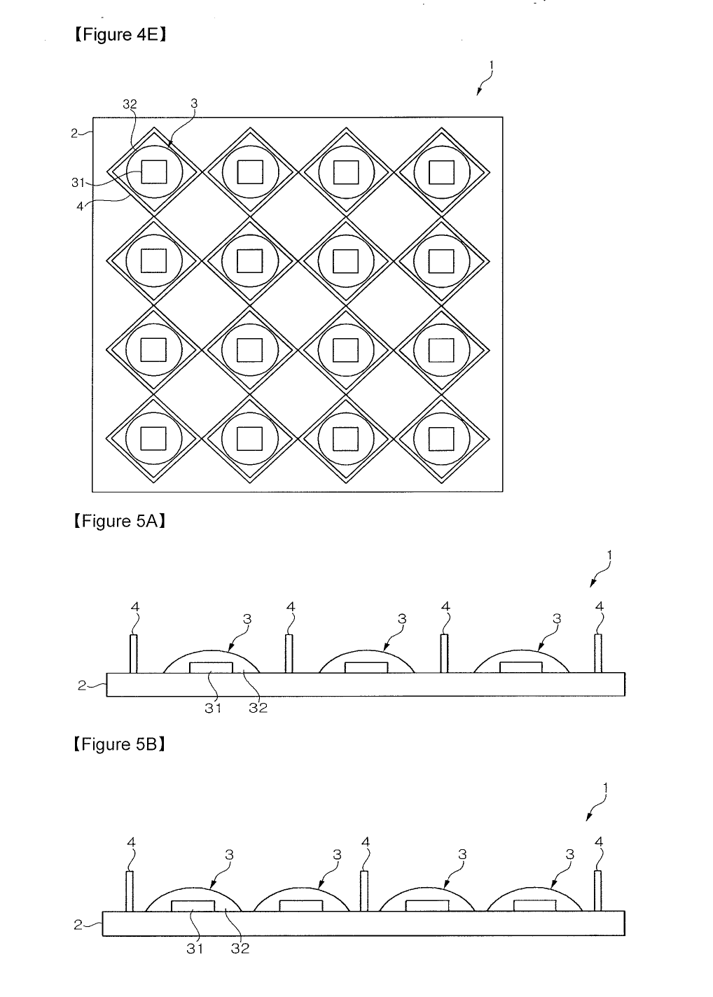

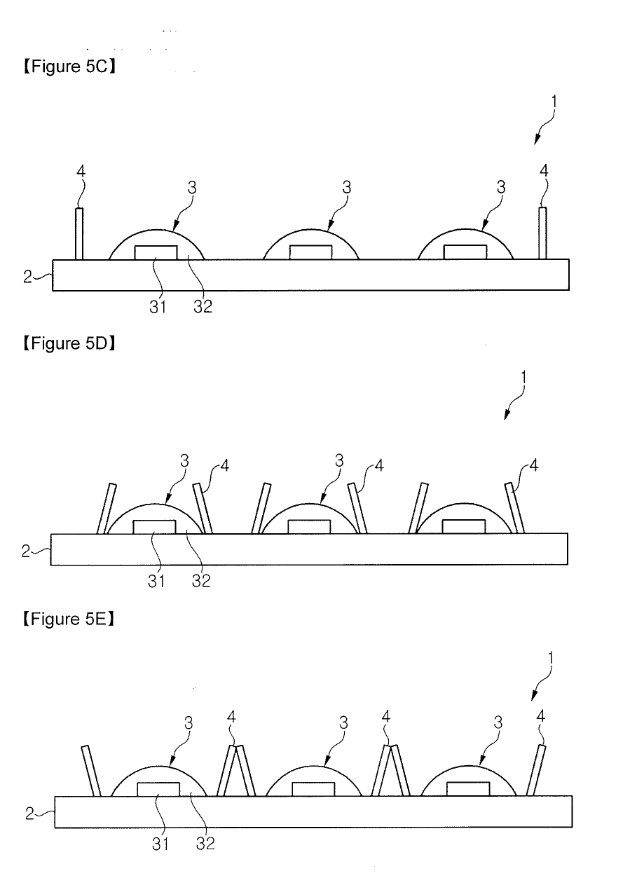

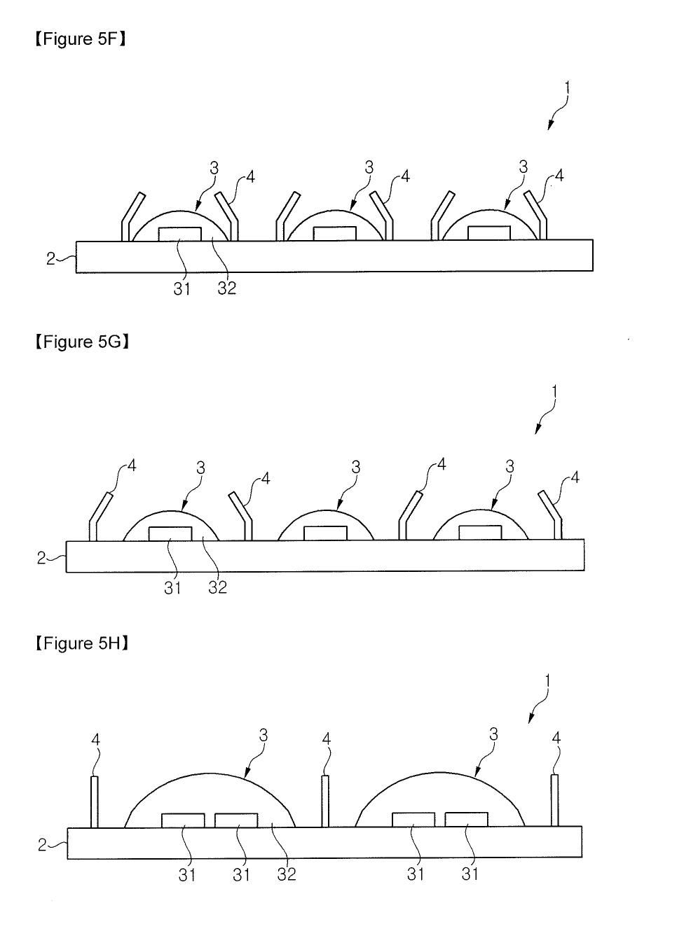

FIGS. 5A through 5H are cross-sectional views illustrating various embodiments of a chip-on-board UV LED package.

In chip-on-board UV LED packages 1 illustrated in FIGS. 5A through 5G, a single encapsulant 32 individually encapsulates a single UV LED chip 31 to form a UV light source 3. In contrast, a chip-on-board UV LED package 1 illustrated in FIG. 5H, a single encapsulant 32 encapsulates a plurality of UV LED chips 31 to form a UV light source 3.

As illustrated in FIG. 5H, the reflectors 4 separate adjacent UV light sources 3, and a plurality of UV LED chips 31 included in a single UV light source 3 are separated from a plurality of UV LED chips 31 included in another UV light source 3 by the reflectors 4.

In the chip-on-board UV LED packages 1 illustrated in FIGS. 5A, 5D, 5E, 5F, 5G, and 5H, a single UV light source 3 is positioned between two adjacent linear reflectors 4 or in a space defined by a single annular reflector 4, while, in the chip-on-board UV LED packages 1 illustrated in FIGS. 5B and 5C, a plurality of UV light sources 3 are positioned between two adjacent linear reflectors 4 or in a space confined by a single annular reflector 4.

The chip-on-board UV LED packages 1 illustrated in FIGS. 5A, 5B, 5C, and 5H include non-extended, non-convergent reflectors 4 confining a reflective space having the same width across the entire height. The chip-on-board UV LED packages 1 illustrated in FIGS. 5D and 5F include convergent reflectors 4 gradually decreasing a reflective space in an upward direction in which UV light is emitted. The chip-on-board UV LED package 1 illustrated in FIG. 5E includes expansion type reflectors 4 gradually increasing a reflective space in an upward direction in which UV light is emitted. The chip-on-board UV LED package 1 illustrated in FIG. 5G includes convergent-and-expanded reflectors 4.

According to the configuration illustrated in FIGS. 5A through 5H, the UV LED chips 31 are mounted on a flat surface. However, as illustrated in FIG. 1, the structure in which a plurality of chip mounting recesses are formed on the surface on which the UV LED chips 31 are mounted, and one or more UV LED chips are mounted in each of the plurality of chip mounting recesses may be applied.

1. A chip-on-board ultraviolet (UV) light emitting diode (LED) package comprising:
a board on which electrode patterns are formed;
UV light sources arranged in a predetermined array on the board and respectively including one or more UV LED chips and an encapsulant or a lens corresponding to the one or more UV LED chips; and
a reflective unit provided on the board to increase an irradiation distance of light emitted from the plurality of UV light sources,
wherein the reflective unit includes at least one reflector disposed to separate adjacent UV light sources or rows or columns of adjacent UV light sources.

2. The chip-on-board UV LED package of claim 1, wherein the reflective unit includes a plurality of annular reflectors attached to the board such that the plurality of annular reflectors respectively surround the peripheries of the UV light sources.

3. The chip-on-board UV LED package of claim 1, wherein the reflective unit includes a plurality of linear reflectors attached to the board to separate rows or columns of the adjacent UV light sources.

4. The chip-on-board UV LED package of claim 1, wherein the reflective unit includes a plurality of reflectors, and the plurality of reflectors include a mirror type reflector and a reflection prism reflector.

5. The chip-on-board UV LED package of claim 1, wherein the reflective unit forms a reflective space with one or more reflectors, a plurality of UV light sources are positioned in the reflective space, and the reflective space is formed within the annular reflectors or between adjacent linear reflectors.

6. The chip-on-board UV LED package of claim 1, wherein the board includes a plurality of chip mounting recesses formed to accommodate the one or more UV LED chips.

7. The chip-on-board UV LED package of claim 1, wherein the reflective unit includes a grid-type reflector including a plurality of grid cells, and the plurality of grid cells respectively form reflective spaces in which the UV light sources are accommodated.

8. A method for manufacturing a chip-on-board ultraviolet (UV) light emitting diode (LED) package, the method comprising:
a UV LED chip mounting operation of mounting a plurality of UV LED chips on a board;
an encapsulant forming operation of forming a plurality of encapsulants encapsulating one or more of the plurality of UV LED chips on the board; and
a reflector attaching operation of attaching one or more reflectors reflecting light from UV light sources including the plurality of UV LED chips or the plurality of UV LED chips and the plurality of encapsulants to the board before or after the plurality of UV LED chips are mounted.

9. The method of claim 8, wherein the encapsulant forming operation includes:
preparing a UV light-transmissive frame board having a plurality of molding recesses;
filling the plurality of molding recesses with a UV-cured resin;
mounting the board on the frame board such that the plurality of UV LED chips are inserted into the plurality of molding recesses filled with the UV-cured resin; and
curing the UV-cured resin with UV light transmitted through the frame board to form the plurality of encapsulants.
